(19) United States
(12) Patent Application Publication
(10) Pub. No.: US 2026/0343850 A1
(43) Pub. Date: Oct. 29, 2026

(54) EPITAXIAL SUPERLATTICE STRUCTURE

(71) Applicant: Applied materials, Inc., Santa Clara, CA (US)

(72) Inventors: Ruiying Hao, San Jose, CA (US); Raghuveer Satya Makala, Campbell, CA (US); Tomohiko Kitajima, San Jose, CA (US); Fredrick Fishburn, Belmont, CA (US); Chang Seok Kang, Santa Clara, CA (US); Amy Child, Gansevoort, NY (US)

(73) Assignee: Applied Materials, Inc., Santa Clara, CA (US)

(21) Appl. No.: 19/374,014

(22) Filed: Oct. 30, 2025

Related U.S. Application Data
(60) Provisional application No. 63/718,868, filed on Nov. 11, 2024.

(51) Int. Cl. H10B 12/00; H10P 14/20; H10P 50/24

(52) U.S. Cl. CPC H10B 12/05; H10P 14/3411; H10P 14/3438; H10P 50/242

(57) ABSTRACT

Methods of reducing wafer bowing in 3D DRAM devices are described using stacks including one or more of epitaxial silicon (Si), carbon doped silicon (SiC), silicon germanium (SiGe), and carbon-doped silicon germanium (SiGeC). A plurality of film stacks is formed on a substrate surface, each of the film stacks comprises two doped silicon layers having different dopant amounts and a sacrificial layer that may be doped or undoped. 3D DRAM devices are also described.

### CROSS-REFERENCE TO RELATED APPLICATIONS

This application claims priority to U.S. Provisional Application No. 63/718,868, filed Nov. 11, 2024, the entire disclosure of which is hereby incorporated by reference herein.

### TECHNICAL FIELD

Embodiments of the disclosure pertain to the field of semiconductor devices and semiconductor device manufacturing. More particularly, embodiments of the disclosure provide three-dimensional dynamic random-access memory (3D DRAM) stacks and methods for forming 3D DRAM devices.

### BACKGROUND

Electronic devices, such as personal computers, workstations, computer servers, mainframes, and other computer related equipment such as printers, scanners and hard disk drives use memory devices that provide substantial data storage capability, while incurring low power consumption. There are two major types of random-access memory cells, dynamic and static, which are well-suited for use in electronic devices. Dynamic random-access memories (DRAMs) can be programmed to store a voltage which represents one of two binary values but require periodic reprogramming or “refreshing” to maintain this voltage for more than very short periods of time. Static random-access memories (SRAM) are so named because they do not require periodic refreshing.

DRAM memory circuits are manufactured by replicating millions of identical circuit elements, known as DRAM cells, on a single semiconductor wafer. Each DRAM cell is an addressable location that can store one bit (binary digit) of data. In its most common form, a DRAM cell consists of two circuit components: a field effect transistor (FET) and a capacitor.

The manufacturing of a DRAM cell includes the fabrication of a transistor, a capacitor, and three contacts: one each to the bitline, the wordline, and the reference voltage. DRAM manufacturing is a highly competitive business. There is continuous pressure to decrease the size of individual cells and to increase memory cell density to allow more memory to be squeezed onto a single memory chip, especially for densities greater than 256 Megabits. Limitations on cell size reduction include the passage of both active and passive wordlines through the cell, the size of the cell capacitor, and the compatibility of array devices with nonarray devices.

To scale the density of the 3D DRAM beyond the 10 nm node, the number of stacks of silicon channel and sacrificial layers needs to be increased to more than 100, which can result in 400 epitaxial layers. The challenge with epitaxial growth of strained silicon channel and sacrificial layers in superlattice heterostructures is the control of stress and epitaxial defectivity due to the lattice mismatch between the silicon channel and sacrificial layers. The lattice constant is 5.431 A for silicon and 5.658 A for germanium. This lattice mismatch can cause compressive stress and induce epitaxial defects generated in the films, resulting in wafer bowing. Typically, wafer bow greater than 200 μm will prevent subsequent processes, such as lithography, from being accurately performed.

Current state of the art processes require additional deposition of stress relieving films at the back side of the wafer to counteract the wafer bowing. This only partially alleviates the wafer bow issue as the bowing returns when a top stack is etched or during thermal processes. Additionally, removing the back side film increases process complexity and costs.

Accordingly, there is a need for 3D DRAM devices and methods of forming 3D DRAM devices with decreased wafer bowing and/or improved etch selectivity.

### SUMMARY

One or more embodiments of the disclosure are directed to methods for forming 3D DRAM devices. In one or more embodiments, the method comprises: forming a plurality of film stacks on a substrate surface, each of the film stacks comprising: a silicon channel layer, a first interfacial layer on the silicon channel layer, the first interfacial layer comprising a doped silicon germanium layer having a first dopant with a first dopant concentration and having a germanium concentration %, a first doped silicon layer on the first interfacial layer, the first doped silicon layer comprising a second dopant having a second dopant concentration, a sacrificial layer on the first doped silicon layer, the sacrificial layer comprising silicon germanium with a germanium concentration, the germanium concentration of the sacrificial layer greater than the germanium concentration of the first interfacial layer, a second doped silicon layer on the sacrificial layer, the second doped silicon layer comprising a third dopant having a third dopant concentration, and a second interfacial layer on the second doped silicon layer, the second interfacial layer comprising a doped silicon germanium layer having a fourth dopant with a fourth dopant concentration and having a germanium concentration, the germanium concentration of the second interfacial layer less than the germanium concentration of the sacrificial layer.

Further embodiments of the disclosure are directed to methods of making a 3D DRAM device. In one or more embodiments, a method comprises: forming a plurality of film stacks on a substrate surface, each of the film stacks comprising: a silicon channel layer, a first interfacial layer on the silicon channel layer, the first interfacial layer comprising a doped silicon germanium layer having a first dopant with a first dopant concentration and having a germanium concentration %, a first doped silicon layer on the first interfacial layer, the first doped silicon layer comprising a second dopant having a second dopant concentration, a sacrificial layer on the first doped silicon layer, the sacrificial layer comprising silicon germanium with a germanium concentration, the germanium concentration of the sacrificial layer greater than the germanium concentration of the first interfacial layer, a second doped silicon layer on the sacrificial layer, the second doped silicon layer comprising a third dopant having a third dopant concentration, and a second interfacial layer on the second doped silicon layer, the second interfacial layer comprising a doped silicon germanium layer having a fourth dopant with a fourth dopant concentration and having a germanium concentration, the germanium concentration of the second interfacial layer less than the germanium concentration of the sacrificial layer.

Additional embodiments of the disclosure are directed to semiconductor superlattice structures. In one or more embodiments, a semiconductor superlattice structure comprises: a plurality of film stacks on a semiconductor substrate, each of the plurality of film stacks comprising: a silicon channel layer; a first doped silicon layer on the silicon channel layer, the first doped silicon layer comprising a first dopant having a first dopant concentration; a second doped silicon layer on the first doped silicon layer, the second doped silicon layer comprising a second dopant having a second dopant concentration, the second dopant concentration greater than the first dopant concentration; a sacrificial layer on the second doped silicon layer, the sacrificial layer comprising silicon germanium; a third doped silicon layer on the sacrificial layer, the third doped silicon layer comprising a third dopant having a third dopant concentration; and a fourth doped silicon layer on the third doped silicon layer, the fourth doped silicon layer comprising a fourth dopant having a fourth dopant concentration, the third dopant concentration greater than the fourth dopant concentration.

Still further embodiments of the disclosure are directed to semiconductor superlattice structures. In one or more embodiments, a semiconductor superlattice structure comprises: a plurality of film stacks on a semiconductor substrate, each of the plurality of film stacks comprising: a silicon channel layer; a first interfacial layer on the silicon channel layer, the first interfacial layer comprising a doped silicon germanium layer having a first dopant with a first dopant concentration and having a germanium concentration; a first doped silicon layer on the first interfacial layer, the first doped silicon layer comprising a second dopant having a second dopant concentration; a sacrificial layer on the first doped silicon layer, the sacrificial layer comprising silicon germanium with a germanium concentration, the germanium concentration of the sacrificial layer greater than the germanium concentration of the first interfacial layer; a second doped silicon layer on the sacrificial layer, the second doped silicon layer comprising a third dopant having a third dopant concentration; and a second interfacial layer on the second doped silicon layer, the second interfacial layer comprising a doped silicon germanium layer having a fourth dopant with a fourth dopant concentration and having a germanium concentration, the germanium concentration of the second interfacial layer less than the germanium concentration of the sacrificial layer.

### BRIEF DESCRIPTION OF THE DRAWINGS

So that the manner in which the features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-section schematic representation of a 3D DRAM device formed according to one or more embodiments of the disclosure;

FIG. 2 shows an expanded view of region II of FIG. 1 after formation of a memory hole opening through the film stacks;

FIG. 2B shows an expanded view of region II of FIG. 1 after etching of a sacrificial layer through the memory hole opening;

FIG. 3 shows a cross-section schematic representation of a 3D DRAM device formed according to one or more embodiments of the disclosure;

FIG. 4 shows an expanded view of region III of FIG. 3 after formation of a memory hole opening through the film stacks; and

FIG. 4B shows an expanded view of region III of FIG. 3 after etching of a sacrificial layer through the memory hole opening.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

In the following description, numerous specific details, such as specific materials, chemistries, dimensions of the elements, etc. are set forth in order to provide thorough understanding of one or more of the embodiments of the present disclosure. It will be apparent, however, to one of ordinary skill in the art that the one or more embodiments of the present disclosure may be practiced without these specific details. In other instances, semiconductor fabrication processes, techniques, materials, equipment, etc., have not been described in great details to avoid unnecessarily obscuring of this description. Those of ordinary skill in the art, with the included description, will be able to implement appropriate functionality without undue experimentation.

While certain exemplary embodiments of the disclosure are described and shown in the accompanying drawings, it is to be understood that such embodiments are merely illustrative and not restrictive of the current disclosure, and that this disclosure is not restricted to the specific constructions and arrangements shown and described because modifications may occur to those ordinarily skilled in the art.

As used in this specification and the appended claims, the terms “precursor”, “reactant”, “reactive gas” and the like are used interchangeably to refer to any gaseous species that can react with the substrate surface.

According to one or more embodiments, the term “on”, with respect to a film or a layer of a film, includes the film or layer being directly on a surface, for example, a substrate surface, as well as there being one or more underlayers between the film or layer and the surface, for example the substrate surface. Thus, in one or more embodiments, the phrase “on the substrate surface” is intended to include one or more underlayers. In other embodiments, the phrase “directly on” refers to a layer or a film that is in contact with a surface, for example, a substrate surface, with no intervening layers. Thus, the phrase “a layer directly on the substrate surface” refers to a layer in direct contact with the substrate surface with no layers in between.

“Atomic layer deposition” or “cyclical deposition” as used herein refers to the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A, e.g., aluminum precursor) is pulsed into the reaction zone followed by a first time delay. Next, a second precursor or compound B (e.g., oxidant) is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, “chemical vapor deposition” refers to a process in which a substrate surface is exposed to precursors and/or co-reagents simultaneously or substantially simultaneously. As used herein, “substantially simultaneously” refers to either co-flow or where there is overlap for a majority of exposures of the precursors.

Plasma enhanced chemical vapor deposition (PECVD) is widely used to deposit thin films due to cost efficiency and film property versatility. In a PECVD process, for example, a hydrocarbon source, such as a gas-phase hydrocarbon or a vapor of a liquid-phase hydrocarbon that have been entrained in a carrier gas, is introduced into a PECVD chamber. A plasma-initiated gas, typically helium, is also introduced into the chamber. Plasma is then initiated in the chamber to create excited CH-radicals. The excited CH-radicals are chemically bound to the surface of a substrate positioned in the chamber, forming the desired film thereon. Embodiments described herein in reference to a PECVD process can be carried out using any suitable thin film deposition system. Any apparatus description described herein is illustrative and should not be construed or interpreted as limiting the scope of the embodiments described herein.

As used herein, the term “epitaxy” refers to a type of crystal growth or material deposition in which new crystalline layers are formed with one or more well-defined orientations with respect to a crystalline seed layer. The deposited crystalline film is called an epitaxial layer.

As used herein, the term “dynamic random-access memory” or “DRAM” refers to a memory cell that stores a datum bit by storing a packet of charge (i.e., a binary one), or no charge (i.e., a binary zero) on a capacitor. The charge is gated onto the capacitor via an access transistor and sensed by turning on the same transistor and looking at the voltage perturbation created by dumping the charge packet on the interconnect line on the transistor output. Thus, a single DRAM cell is made of one transistor and one capacitor. The DRAM device is formed of an array of DRAM cells.

Traditionally, DRAM cells have recessed high work-function metal structures in buried word line structure. In a DRAM device, a bit line is formed in a metal level situated above the substrate, while the word line is formed at the polysilicon gate level at the surface of the substrate. In the buried word line (bWL), a word line is buried below the surface of a semiconductor substrate using a metal as a gate electrode.

The embodiments of the disclosure are described by way of the Figures, which illustrate devices (e.g., 3D DRAM) and processes for forming devices in accordance with one or more embodiments of the disclosure. The processes shown are merely illustrative possible uses for the disclosed processes, and the skilled artisan will recognize that the disclosed processes are not limited to the illustrated applications.

One or more embodiments of the disclosure advantageously provide methods for forming 3D DRAM devices with film stacks having decreased or neutral bow. Some embodiments advantageously provide 3D DRAM film stacks including one or more of epitaxial silicon (Si), carbon doped silicon (SiC), silicon germanium (SiGe), and carbon-doped silicon germanium (SiGeC) with decreased or neutral bow.

Although the disclosure will routinely identify specific 3D DRAM devices, and components thereof, it will be readily understood that the device and methods are equally applicable to other memory devices, orientations thereof, as processes for forming such devices. Accordingly, the technology should not be considered to be so limited as for use with these specific devices or methods alone. The disclosure will discuss one possible semiconductor device that may include one or more components, utilizing word line contacts formed on both the top side and bottom side, so that the same number of word line contacts are formed in a reduced word line contact area according to embodiments of the present technology before additional variations and adjustments to this apparatus according to embodiments of the present technology are described.

In one or more embodiments, metal deposition and other processes can be carried out in an isolated environment (e.g., a cluster process tool). Accordingly, some embodiments of the disclosure provide integrated tool systems with related process modules to implement the methods.

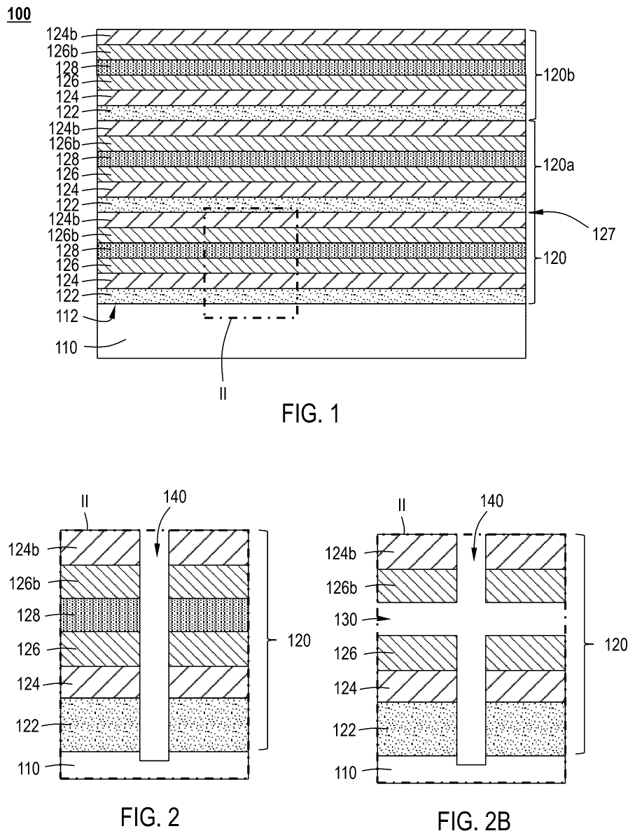

Referring to FIGS. 1 and 2, one or more embodiments of the disclosure are directed to methods for reducing wafer bowing in 3D DRAM devices 100 using sacrificial layers that have varying levels of carbon, silicon, and germanium content. A plurality of film stacks 120 are formed on a substrate 110 having a substrate surface 112.

The substrate 110 can be any suitable material known to the skilled artisan. As used in this specification and the appended claims, the term “substrate” refers to a surface, or portion of a surface, upon which a process acts. It will also be understood by those skilled in the art that reference to a substrate can refer to only a portion of the substrate unless the context clearly indicates otherwise. Additionally, reference to depositing on a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present disclosure, any of the film processing steps disclosed may also be performed on an under-layer formed on the substrate as disclosed in more detail below, and the term “substrate surface” is intended to include such under-layer as the context indicates. Thus, for example, where a film/layer or partial film/layer has been deposited onto a substrate surface, the exposed surface of the newly deposited film/layer becomes the substrate surface.

The embodiment illustrated in FIG. 1 shows three film stacks 120 (including films stacks 120a, 120b). The skilled artisan will recognize that this is merely representative and that there can be more or less film stacks 120. In some embodiments, there are greater than 50, 100, 150, or 200 film stacks 120.

At least some of the film stacks 120, or each of the film stacks 120, comprises a silicon channel layer 122, a first doped silicon layer 124, a second doped silicon layer 126, and a sacrificial layer 128. The skilled artisan will recognize that the silicon channel layer 122 in the first stack 120a is formed on the substrate surface 112, or directly on the substrate surface 112. The silicon channel layers 122 of subsequent film stacks 120a are formed on the surface 127 of the first doped silicon layer 124 of the previous film stack 120.

In one or more embodiments, the silicon channel layer 122 has a thickness in a range of from greater than 0 nm to 50 nm, including in a range of from greater than 0 nm to 35 nm, including about 2 nm, about 5 nm, about 7 nm, about 10 nm, about 12 nm, about 15 nm, about 17 nm, about 20 nm, about 22 nm, about 25 nm, about 27 nm, about 30 nm, about 32 nm, about 35 nm, about 37 nm, about 40 nm, about 42 nm, about 45 nm, about 47 nm, and about 50 nm. In one or more embodiments, the silicon channel layer 122 comprises, consists essentially of, or consists of epitaxial silicon. The epitaxial silicon is completely or mostly single crystal.

In one or more embodiments, a first doped silicon layer 124 is formed on, or directly on the silicon channel layer 122. In one or more embodiments, the first doped silicon layer 124 comprises silicon doped with a dopant. The dopant may comprise any suitable dopant as described herein. In one or more embodiments, the dopant comprises carbon (C), so the first doped silicon layer 124 comprises carbon-doped silicon (SiC). In some embodiments, the first doped silicon layer 124 comprises a dopant with a dopant concentration in the range of greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %, or in a range of from greater than 0 atomic % to 0.3 atomic %, or in a range of from greater than 0 atomic % to 0.2 atomic %, or in a range of from greater than 0 atomic % to 0.1 atomic %.

In one or more embodiments, the first doped silicon layer 124 is graded for carbon (C) content to form a carbon-doped silicon layer having a carbon gradient. As used herein, the term “gradient” refers to a variation in the concentration throughout the thickness of a material. In other words, the first doped silicon layer 124 has a carbon gradient in which the concentration of carbon (C) gradually changes throughout the thickness of the first doped silicon layer 124. In one or more embodiments, the carbon (C) concentration ranges from low to high, where the carbon (C) concentration is lowest at the interface with the silicon channel layer 122 and highest at the interface with the second doped silicon layer 126. In other embodiments, the carbon (C) concentration ranges from high to low, where the carbon (C) concentration is highest at the interface with the silicon channel layer 122 and lowest at the interface with the second doped silicon layer 126. In one or more embodiments, the concentration of carbon (C) in the first doped silicon layer 124 is in a range of from 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %, or in a range of from greater than 0 atomic % to 0.3 atomic %, or in a range of from greater than 0 atomic % to 0.2 atomic %, or in a range of from greater than 0 atomic % to 0.1 atomic %.

In one or more embodiments, the first doped silicon layer 124 has any suitable thickness. In some embodiments, the first doped silicon layer 124 has a thickness in a range of from greater than 0 nm to 30 nm, including in a range of from greater than 0 nm to 25 nm, including in a range of from greater than 0 nm to 20 nm, including in a range of from greater than 0 nm to 15 nm, including in a range of from 1 nm to 12 nm, or in a range of from 1 nm to 10 nm, or in a range of from 5 nm to 10 nm.

In one or more embodiments, a second doped silicon layer 126 is formed on, or directly on the first doped silicon layer 124. In one or more embodiments, the second doped silicon layer 126 comprises silicon doped with a dopant. In one or more embodiments, the dopant comprises carbon (C), so the second doped silicon layer 126 comprises carbon-doped silicon (SiC). In some embodiments, the second doped silicon layer 126 comprises a dopant with a dopant concentration in the range of greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the second doped silicon layer 126 is graded for carbon (C) content to form a carbon-doped silicon layer having a carbon gradient. In one or more embodiments, the second doped silicon layer 126 has a carbon gradient in which the concentration of carbon (C) gradually changes throughout the thickness of the second doped silicon layer 126. In one or more embodiments, the carbon (C) concentration ranges from low to high, where the carbon (C) concentration is lowest at the interface with the first doped silicon layer 124 and highest at the interface with the doped silicon germanium layer 128. In one or more embodiments, the carbon (C) concentration ranges from high to low, where the carbon (C) concentration is highest at the interface with the first doped silicon layer 124 and lowest at the interface with the doped silicon germanium layer 128. In one or more embodiments, the concentration of carbon (C) in the second doped silicon layer 126 is in a range of from 0 atomic % to 2.5 atomic %, or in a range of from greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the second doped silicon layer 126 has any suitable thickness. In some embodiments, the second doped silicon layer 126 has a thickness in a range of from greater than 0 nm to 30 nm, including in a range of from greater than 0 nm to 25 nm, including in a range of from greater than 0 nm to 20 nm, including in a range of from greater than 0 nm to 15 nm, including in a range of from 1 nm to 12 nm, or in a range of from 1 nm to 10 nm, or in a range of from 5 nm to 10 nm.

In one or more embodiments, a sacrificial layer 128 is formed on, or directly on the second doped silicon layer 126. In one or more embodiments, the sacrificial layer 128 comprises doped silicon germanium layer. The dopant may comprise any suitable dopant. In one or more embodiments, the dopant comprises carbon (C), and the sacrificial layer 128 comprises carbon-doped silicon germanium (SiGeC). In one or more embodiments, the sacrificial layer 128 has an empirical formula SiₓGe_{y}C_{z}. In some embodiments, x is in a range of from greater than 0.7 to 0.95, y is in the range of greater than 0.05 to 0.3, and z is in a range of from 0 to 0.025. In some embodiments, y is in the range of greater than 0.1 to 0.25, or in the range of greater than 0.12 to 0.2, or in the range of greater than 0.13 to 0.18. In some embodiments, x is in the range of 0.75, 0.80, 0.85, 0.88 or 0.90 to 0.95.

In one or more embodiments, the sacrificial layer 128 has a dopant concentration in the range of greater than 0 atomic % to 5 atomic %, including in a range of from greater than 0 atomic % to 2.5 atomic %, including in a range of from 0.1 atomic % to 2 atomic %, including in a range of from 0.1 atomic % to 1.5 atomic %, including in a range of from 0.1 atomic % to 1 atomic %. In some embodiments, the sacrificial layer 128 has a dopant concentration in the range of 0.01, 0.02, 0.03, 0.04, 0.05, 0.06, 0.07, 0.08, 0.09, or 0.1 atomic % to 1 atomic %. In some embodiments, the sacrificial layer 128 has a dopant concentration in the range of 0.01 atomic % to 0.1, 0.2, 0.3, 0.4, 0.5, 0.6, 0.7, 0.8, 0.9 or 1 atomic %.

In one or more embodiments, the sacrificial layer 128 comprises a doped silicon germanium layer having a germanium concentration or germanium content in a range of from greater than 0 atomic % to 30 atomic % germanium, including in a range of from greater than 0 atomic % to 25 atomic % germanium, including in a range of from greater than 0 atomic % to 25 atomic % germanium, including in a range of from greater than 0 atomic % to 15 atomic % germanium, including in a range of from 5 atomic % to 15 atomic %, including in a range of from 10 atomic % to 30 atomic % germanium, and including in a range of from 10 atomic % to 25 atomic %. In one or more embodiments, the sacrificial layer 128 comprises a doped silicon germanium layer having a germanium content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, about 10 atomic %, about 11 atomic %, about 12 atomic %, about 13 atomic %, about 14 atomic %, about 15 atomic %, about 16 atomic %, about 17 atomic %, about 18 atomic %, about 19 atomic %, about 20 atomic %, about 21 atomic %, about 22 atomic %, about 23 atomic %, about 24 atomic %, about 25 atomic %, about 26 atomic %, about 27 atomic %, about 28 atomic %, about 29 atomic %, or about 30 atomic %.

In one or more embodiments, the film stack 120 also includes a third doped silicon layer 126b formed on the sacrificial layer 128. In one or more embodiments, the third doped silicon layer 126b comprises silicon doped with a dopant. In one or more embodiments, the dopant comprises carbon (C), so the third doped silicon layer 126b comprises carbon-doped silicon (SiC). In some embodiments, the third doped silicon layer 126b comprises a dopant with a dopant concentration in the range of greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the third doped silicon layer 126b is graded for carbon (C) content to form a carbon-doped silicon layer having a carbon gradient. In one or more embodiments, the third doped silicon layer 126b has a carbon gradient in which the concentration of carbon (C) gradually changes throughout the thickness of the third doped silicon layer 126b. In one or more embodiments, the carbon (C) concentration ranges from low to high, where the carbon (C) concentration is lowest at the interface with the fourth doped silicon layer 124b and highest at the interface with the sacrificial layer 128. In one or more embodiments, the carbon (C) concentration ranges from high to low, where the carbon (C) concentration is highest at the interface with the fourth doped silicon layer 124b and lowest at the interface with the sacrificial layer 128. In one or more embodiments, the concentration of carbon (C) in the third doped silicon layer 126b is in a range of from 0 atomic % to 2.5 atomic %, or in a range of from greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the third doped silicon layer 126b has any suitable thickness. In some embodiments, the third doped silicon layer 126b has a thickness in a range of from greater than 0 nm to 30 nm, including in a range of from greater than 0 nm to 25 nm, including in a range of from greater than 0 nm to 20 nm, including in a range of from greater than 0 nm to 15 nm, including in a range of from 1 nm to 12 nm, or in a range of from 1 nm to 10 nm, or in a range of from 5 nm to 10 nm.

In one or more embodiments, a fourth doped silicon layer 124b is formed on, or directly on the third doped silicon layer 126b. In one or more embodiments, the fourth doped silicon layer 124b comprises silicon doped with a dopant. The dopant may comprise any suitable dopant as described herein. In one or more embodiments, the dopant comprises carbon (C), so the fourth doped silicon layer 124b comprises carbon-doped silicon (SiC). In some embodiments, the fourth doped silicon layer 124b comprises a dopant with a dopant concentration in the range of greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %, or in a range of from greater than 0 atomic % to 0.3 atomic %, or in a range of from greater than 0 atomic % to 0.2 atomic %, or in a range of from greater than 0 atomic % to 0.1 atomic %.

In one or more embodiments, the fourth doped silicon layer 124b is graded for carbon (C) content to form a carbon-doped silicon layer having a carbon gradient. In one or more embodiments, the fourth doped silicon layer 124b has a carbon gradient in which the concentration of carbon (C) gradually changes throughout the thickness of the fourth doped silicon layer 124b. In one or more embodiments, the carbon (C) concentration ranges from low to high, where the carbon (C) concentration is lowest at the interface with the silicon channel layer 122 and highest at the interface with the third doped silicon layer 126b. In one or more embodiments, the carbon (C) concentration ranges from high to low, where the carbon (C) concentration is highest at the interface with the silicon channel layer 122 and lowest at the interface with the third doped silicon layer 126b. In one or more embodiments, the concentration of carbon (C) in the fourth doped silicon layer 124b is in a range of from 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %, or in a range of from greater than 0 atomic % to 0.3 atomic %, or in a range of from greater than 0 atomic % to 0.2 atomic %, or in a range of from greater than 0 atomic % to 0.1 atomic %.

In one or more embodiments, the fourth doped silicon layer 124b has any suitable thickness. In some embodiments, the fourth doped silicon layer 124b has a thickness in a range of from greater than 0 nm to 30 nm, including in a range of from greater than 0 nm to 25 nm, including in a range of from greater than 0 nm to 20 nm, including in a range of from greater than 0 nm to 15 nm, including in a range of from 1 nm to 12 nm, or in a range of from 1 nm to 10 nm, or in a range of from 5 nm to 10 nm.

The dopant in any of the first doped silicon layer 124, second doped silicon layer 126, sacrificial layer 128, third doped silicon layer 126b, and fourth doped silicon layer 124b can be any suitable dopant known to the skilled artisan. In some embodiments, the dopant comprises a Group III-V element. In some embodiments, the dopant comprises one or more of carbon (C), boron (B), nitrogen (N), phosphorus (P), or oxygen (O). In some embodiments, the dopant comprises one or more of carbon (C) or boron (B). In other embodiments, the dopant comprises carbon (C). In some embodiments, the dopant consists essentially of one or more of carbon or boron. In other embodiments, the dopant consists essentially of carbon (C). As used in this manner, the term “consists essentially of” means that the composition of the subject component is greater than or equal to 95%, 98%, 99% or 99.5% of the stated material. For example, a dopant consisting essentially of carbon and/or boron means that out of all dopant atoms, greater than or equal to 95% are carbon or boron. In some embodiments, the dopant comprises or consists essentially of carbon. In some embodiments, the dopant comprises or consists essentially of boron.

The various layers described can be formed by any suitable technique known to the skilled artisan. For example, one or more of the films can be formed by epitaxial growth, chemical vapor deposition, atomic layer deposition, physical vapor deposition, ion implantation, etc. In some embodiments, each of the silicon channel layer 122, the first doped silicon layer 124, the second doped silicon layer 126, the sacrificial layer 128, the third doped silicon layer 126b, and the fourth doped silicon layer 124b are epitaxially grown. In some embodiments, each of the silicon channel layer 122, the first doped silicon layer 124, the second doped silicon layer 126, the sacrificial layer 128, the third doped silicon layer 126b, and the fourth doped silicon layer 124b are independently grown at a temperature in the range of 500° C. to 800° C.

In one or more embodiments, the stress of the film stack 120 is modulated by the doped layers, which advantageously reduces bowing of the wafer upon which the film stack(s) 120 is deposited. In some embodiments, the overall bowing of the wafer is neutral after formation of 100 film stacks 120. In some embodiments, the overall bowing of the wafer is neutral after formation of 125, 150, 175, or 200 film stacks 120. As used in this manner, the term “neutral” means that there is less than or equal to 200 μm, 175 μm, 150 μm, 125 μm, 100 μm, 75 μm, 50 μm, 25 μm bow across the wafer surface; with the center of the wafer either bowing up or bowing down with respect to some or all of the edge regions. Some embodiments provide a method of doping epitaxial films in a controlled manner to result in reduced wafer bow of 30 μm or less for 1 μm tall stack making a 5 μm or greater DRAM stack height with neutral wafer bow.

In one or more embodiments, a method of making a 3D DRAM device is provided. In some embodiments, the method includes forming a plurality of film stacks 120, 120a, 120b on a substrate surface 112. Each of the film stacks 120, 120a, 120b may include a silicon channel layer 122. In one or more embodiments, a first doped silicon layer 124 is on, or directly on, the silicon channel layer 122. In some embodiments, the first doped silicon layer 124 has a first dopant having a first dopant concentration in a range of from greater than 0 atomic % to 2.5 atomic %. A second doped silicon layer 126 is on, or directly on, the first doped silicon layer 124. In some embodiments, the second doped silicon layer 126 includes a second dopant having a second dopant concentration in a range of from greater than 0 atomic % to 2.5 atomic %. In one or more embodiments, the second dopant concentration is greater than the first dopant concentration. A sacrificial layer 128 is on, or directly on, the second doped silicon layer 126. In some embodiments, the sacrificial layer 128 comprises doped silicon germanium with a sacrificial dopant concentration in a range of from greater than 0 atomic % to 2.5 atomic % and a germanium concentration in a range of from greater than 0 atomic % to 25 atomic %. In one or more embodiments, a third doped silicon layer 126b is on, or directly on, the sacrificial layer 128. In some embodiments, the third doped silicon layer 126b comprises a third dopant having a third dopant concentration in a range of from greater than 0 atomic % to 2.5 atomic %. In one or more embodiments, a fourth doped silicon layer 124b is on, or directly on, the third doped silicon layer 126b. In some embodiments, the fourth doped silicon layer 124b comprises a fourth dopant having a fourth dopant concentration in a range of from greater than 0 atomic % to 2.5 atomic %. In one or more embodiments, a memory hole opening 140 is formed through the plurality of film stacks 120, 120a, 120b to the substrate 110.

In one or more embodiments, each of the first doped silicon layer, the second doped silicon layer, the third doped silicon layer, the fourth doped silicon layer, and the sacrificial layer independently have a thickness in a range of from greater than 0 nm to 25 nm. In some embodiments, each of the first doped silicon layer, the second doped silicon layer, the third doped silicon layer, the fourth doped silicon layer, and the sacrificial layer have substantially the same thickness. As used herein, the term “substantially the same” means that the thickness of each of the first doped silicon layer, the second doped silicon layer, the third doped silicon layer, the fourth doped silicon layer, and the sacrificial layer varies by less than or equal to ±10% relative to the thickness of the other layer. In some embodiments, each of the first doped silicon layer, the second doped silicon layer, the third doped silicon layer, the fourth doped silicon layer, and the sacrificial layer has a thickness that varies by less than or equal to ±5%, less than or equal to ±4%, less than or equal to ±3%, less than or equal to ±2% or less than or equal to ±1%.

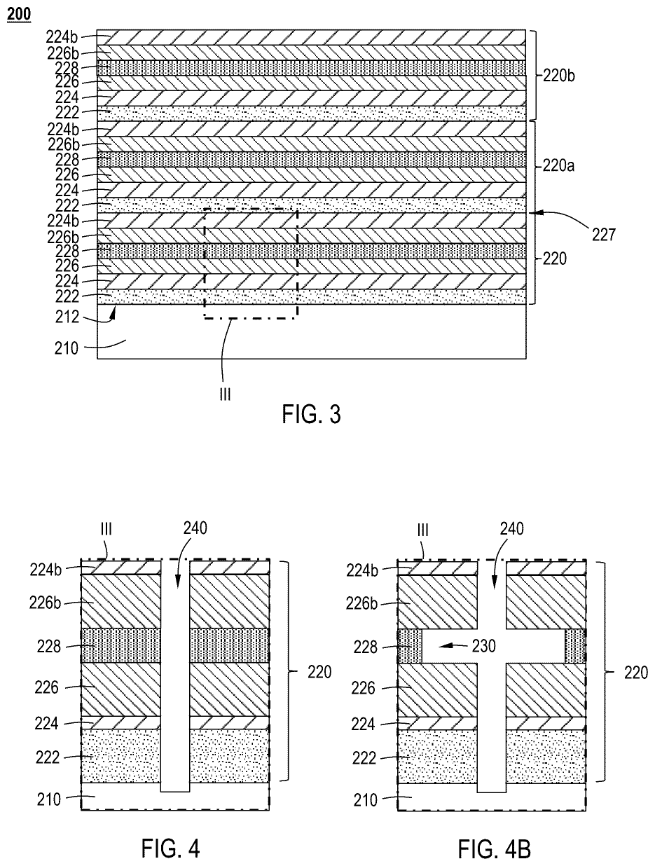

Referring to FIGS. 3 and 4, one or more embodiments of the disclosure are directed to methods for reducing wafer bowing in 3D DRAM devices 200 using sacrificial layers that have varying levels of carbon, silicon, and germanium content. A plurality of film stacks 220 are formed on a substrate 210 having a substrate surface 212.

The substrate 210 can be any suitable material known to the skilled artisan as described herein with respect to the substrate 110 of FIG. 1.

The embodiment illustrated in FIG. 3 shows three film stacks 220 (including films stacks 220a, 220b). The skilled artisan will recognize that this is merely representative and that there can be more or less film stacks 220. In some embodiments, there are greater than 50, 100, 150, or 200 film stacks 220.

At least some of the film stacks 220, or each of the film stacks 220, comprises a silicon channel layer 222, an interfacial layer 224, a first doped silicon layer 226, and a sacrificial layer 228. The skilled artisan will recognize that the silicon channel layer 222 in the first stack 220a may be formed on the substrate surface 212, or directly on the substrate surface 212. The silicon channel layers 222 of subsequent film stacks 220a are formed on the surface 227 of the interfacial layer 224 of the previous film stack 220.

In one or more embodiments, the silicon channel layer 222 has a thickness in a range of from greater than 0 nm to 50 nm, including about 2 nm, about 5 nm, about 7 nm, about 10 nm, about 12 nm, about 15 nm, about 17 nm, about 20 nm, about 22 nm, about 25 nm, about 27 nm, about 30 nm, about 32 nm, about 35 nm, about 37 nm, about 40 nm, about 42 nm, about 45 nm, about 47 nm, and about 50 nm. In one or more embodiments, the silicon channel layer 222 comprises, consists essentially of, or consists of epitaxial silicon. The epitaxial silicon may be amorphous or crystalline.

In one or more embodiments, an interfacial layer 224 is formed on, or directly on the silicon channel layer 222. In one or more embodiments, the interfacial layer 224 comprises silicon germanium (SiGe) doped with a dopant. The dopant may comprise any suitable dopant as described herein. In one or more embodiments, the dopant comprises carbon (C), so the interfacial layer 224 comprises carbon-doped silicon germanium (SiGeC). In some embodiments, the interfacial layer 224 comprises silicon germanium having a dopant with a dopant concentration in the range of greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %, or in a range of from greater than 0 atomic % to 0.3 atomic %, or in a range of from greater than 0 atomic % to 0.2 atomic %, or in a range of from greater than 0 atomic % to 0.1 atomic %.

In one or more embodiments, the interfacial layer 224 comprises carbon-doped silicon germanium (SiGeC). In one or more embodiments, the interfacial layer 224 has an empirical formula SiₓGe_{y}C_{z}. In some embodiments, x is in a range of from greater than 0.7 to 0.95, y is in the range of greater than 0.05 to 0.3, and z is in a range of from 0 to 0.025. In some embodiments, y is in the range of greater than 0.1 to 0.25, or in the range of greater than 0.12 to 0.2, or in the range of greater than 0.13 to 0.18. In some embodiments, x is in the range of 0.75, 0.80, 0.85, 0.88 or 0.90 to 0.95.

In one or more embodiments, the interfacial layer 224 is graded for carbon (C) content to form a carbon-doped silicon germanium layer having a carbon gradient. In some embodiments, the interfacial layer 224 has a carbon gradient in which the concentration of carbon (C) gradually changes throughout the thickness of the interfacial layer 224. In one or more embodiments, the carbon (C) concentration ranges from low to high, where the carbon (C) concentration is lowest at the interface with the silicon channel layer 222 and highest at the interface with the first doped silicon layer 226. In one or more embodiments, the carbon (C) concentration ranges from high to low, where the carbon (C) concentration is highest at the interface with the silicon channel layer 222 and lowest at the interface with the first doped silicon layer 226. In one or more embodiments, the concentration of carbon (C) in the interfacial layer 224 is in a range of from 0 atomic % to 2.5 atomic %, or in a range of from greater than 0 atomic % to 1 atomic %, or in a range of from greater than 0 atomic % to 0.9 atomic %, or in a range of from greater than 0 atomic % to 0.8 atomic %, or in a range of from greater than 0 atomic % to 0.7 atomic %, or in a range of from greater than 0 atomic % to 0.6 atomic %. In one or more embodiments, the concentration of dopant in the interfacial layer 224 is greater than 0 atomic %, 0.01 atomic %, 0.02 atomic %, 0.03 atomic %, 0.04 atomic %, 0.05 atomic %, 0.06 atomic %, 0.07 atomic %, 0.08 atomic %, 0.09 atomic %, 0.1 atomic %, 0.15 atomic %, 0.2 atomic %, 0.25 atomic %, 0.3 atomic %, 0.35 atomic %, 0.4 atomic %, 0.45 atomic %, 0.5 atomic %, 0.55 atomic %, 0.6 atomic %, 0.65 atomic %, 0.7 atomic %, 0.75 atomic %, 0.8 atomic %, 0.85 atomic %, 0.9 atomic %, 0.95 atomic %, or 1.0 atomic %.

In one or more embodiments, the interfacial layer 224 comprises a doped silicon germanium layer having a germanium concentration or germanium content in a range of from greater than 0 atomic % to 20 atomic % germanium, including in a range of from greater than 0 atomic % to 15 atomic % germanium, including in a range of from 5 atomic % to 15 atomic %, and including in a range of from 10 atomic % to 15 atomic %. In one or more embodiments, the interfacial layer 224 comprises a doped silicon germanium layer having a germanium content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, about 10 atomic %, about 11 atomic %, about 12 atomic %, about 13 atomic %, about 14 atomic %, about 15 atomic %, about 16 atomic %, about 17 atomic %, about 18 atomic %, about 19 atomic %, or about 20 atomic %.

In one or more embodiments, the interfacial layer 224 has any suitable thickness. In some embodiments, the interfacial layer 224 has a thickness in a range of from greater than 0 nm to 10 nm, including in a range of from greater than 0 nm to 8 nm, including in a range of from greater than 0 nm to 5 nm, including in a range of from greater than 0 nm to 3 nm, including in a range of from 1 nm to 5 nm, or in a range of from 1 nm to 3 nm, or in a range of from 1 nm to 2.5 nm. In one or more embodiments, the interfacial layer 224 has a thickness of about greater than 0 nm, about 0.5 nm, about 1 nm, about 1.5 nm, about 2 nm, about 2.5 nm, about 3 nm, about 3.5 nm, about 4 nm, about 4.5 nm, about 5 nm, about 5.5 nm, about 6 nm, about 6.5 nm, about 7 nm, about 7.5 nm, about 8 nm, about 8.5 nm, about 9 nm, about 9.5 nm, or about 10 nm.

In one or more embodiments, a first doped silicon layer 226 is formed on, or directly on the interfacial layer 224. In one or more embodiments, the first doped silicon layer 226 comprises silicon doped with a dopant. The dopant may comprise any suitable dopant. In one or more embodiments, the dopant comprises carbon (C), so the first doped silicon layer 226 comprises carbon-doped silicon (SiC). In some embodiments, the first doped silicon layer 226 comprises a dopant with a dopant concentration in the range of greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the first doped silicon layer 226 is graded for carbon (C) content to form a carbon-doped silicon layer having a carbon gradient. In one or more embodiments, the first doped silicon layer 226 has a carbon gradient in which the concentration of carbon (C) gradually changes throughout the thickness of the first doped silicon layer 226. In one or more embodiments, the carbon (C) concentration ranges from low to high, where the carbon (C) concentration is lowest at the interface with the interfacial layer 224 and highest at the interface with the sacrificial layer 228. In one or more embodiments, the carbon (C) concentration ranges from high to low, where the carbon (C) concentration is highest at the interface with the interfacial layer 224 and lowest at the interface with the sacrificial layer 228. In one or more embodiments, the concentration of carbon (C) in the first doped silicon layer 226 is in a range of from 0 atomic % to 2.5 atomic %, or in a range of from greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the first doped silicon layer 226 has any suitable thickness. In some embodiments, the first doped silicon layer 226 has a thickness in a range of from greater than 0 nm to 40 nm, including in a range of from greater than 0 nm to 35 nm, including in a range of from greater than 0 nm to 30 nm, including in a range of from greater than 0 nm to 25 nm, including in a range of from greater than 0 nm to 20 nm, including in a range of from 1 nm to 40 nm, including in a range of from 1 nm to 30 nm, or in a range of from 1 nm to 25 nm, or in a range of from 5 nm to 25 nm.

In one or more embodiments, a sacrificial layer 228 is formed on, or directly on the first doped silicon layer 226. In one or more embodiments, the sacrificial layer 228 comprises a doped silicon germanium layer having a germanium concentration or germanium content in a range of from greater than 0 atomic % to 30 atomic % germanium, including in a range of from greater than 0 atomic % to 25 atomic % germanium, including in a range of from greater than 0 atomic % to 25 atomic % germanium, including in a range of from greater than 0 atomic % to 15 atomic % germanium, including in a range of from 5 atomic % to 15 atomic %, including in a range of from 10 atomic % to 30 atomic % germanium, and including in a range of from 10 atomic % to 25 atomic %. In one or more embodiments, the sacrificial layer 228 comprises a doped silicon germanium layer having a germanium content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, about 10 atomic %, about 11 atomic %, about 12 atomic %, about 13 atomic %, about 14 atomic %, about 15 atomic %, about 16 atomic %, about 17 atomic %, about 18 atomic %, about 19 atomic %, about 20 atomic %, about 21 atomic %, about 22 atomic %, about 23 atomic %, about 24 atomic %, about 25 atomic %, about 26 atomic %, about 27 atomic %, about 28 atomic %, about 29 atomic %, or about 30 atomic %.

In one or more embodiments, a second doped silicon layer 226b is formed on, or directly on the sacrificial layer 228. In one or more embodiments, the second doped silicon layer 226b comprises silicon doped with a dopant. The dopant may comprise any suitable dopant. In one or more embodiments, the dopant comprises carbon (C), so the second doped silicon layer 226b comprises carbon-doped silicon (SiC). In some embodiments, the second doped silicon layer 226b comprises a dopant with a dopant concentration in the range of greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the second doped silicon layer 226b is graded for carbon (C) content to form a carbon-doped silicon layer having a carbon gradient. In one or more embodiments, the second doped silicon layer 226b has a carbon gradient in which the concentration of carbon (C) gradually changes throughout the thickness of the second doped silicon layer 226b. In one or more embodiments, the carbon (C) concentration ranges from low to high, where the carbon (C) concentration is lowest at the interface with the interfacial layer 224b and highest at the interface with the sacrificial layer 228. In one or more embodiments, the carbon (C) concentration ranges from high to low, where the carbon (C) concentration is highest at the interface with the interfacial layer 224b and lowest at the interface with the sacrificial layer 228. In one or more embodiments, the concentration of carbon (C) in the second doped silicon layer 226b is in a range of from 0 atomic % to 2.5 atomic %, or in a range of from greater than 0 atomic % to 5 atomic %, or in a range of from greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %.

In one or more embodiments, the second doped silicon layer 226b has any suitable thickness. In some embodiments, the second doped silicon layer 226b has a thickness in a range of from greater than 0 nm to 40 nm, including in a range of from greater than 0 nm to 35 nm, including in a range of from greater than 0 nm to 30 nm, including in a range of from greater than 0 nm to 25 nm, including in a range of from greater than 0 nm to 20 nm, including in a range of from 1 nm to 40 nm, including in a range of from 1 nm to 30 nm, or in a range of from 1 nm to 25 nm, or in a range of from 5 nm to 25 nm.

In one or more embodiments, a second interfacial layer 224b is formed on, or directly on the second doped silicon layer 226b. In one or more embodiments, the second interfacial layer 224b comprises silicon germanium (SiGe) doped with a dopant. The dopant may comprise any suitable dopant as described herein. In one or more embodiments, the dopant comprises carbon (C), so the second interfacial layer 224b comprises carbon-doped silicon germanium (SiGeC). In some embodiments, the second interfacial layer 224b comprises silicon germanium having a dopant with a dopant concentration in the range of greater than 0 atomic % to 2.5 atomic %, or in a range of from greater than 0 atomic % to 1 atomic %, or in a range of from greater than 0 atomic % to 0.5 atomic %, or in a range of from greater than 0 atomic % to 0.4 atomic %, or in a range of from greater than 0 atomic % to 0.3 atomic %, or in a range of from greater than 0 atomic % to 0.2 atomic %, or in a range of from greater than 0 atomic % to 0.1 atomic %.

In one or more embodiments, the second interfacial layer 224b comprises carbon-doped silicon germanium (SiGeC). In one or more embodiments, the second interfacial layer 224b has an empirical formula SiₓGe_{y}C_{z}. In some embodiments, x is in a range of from greater than 0.7 to 0.95, y is in the range of greater than 0.05 to 0.3, and z is in a range of from 0 to 0.025. In some embodiments, y is in the range of greater than 0.1 to 0.25, or in the range of greater than 0.12 to 0.2, or in the range of greater than 0.13 to 0.18. In some embodiments, x is in the range of 0.75, 0.80, 0.85, 0.88 or 0.90 to 0.95.

In one or more embodiments, the second interfacial layer 224b is graded for carbon (C) content to form a carbon-doped silicon germanium layer having a carbon gradient. In some embodiments, the second interfacial layer 224b has a carbon gradient in which the concentration of carbon (C) gradually changes throughout the thickness of the second interfacial layer 224b. In one or more embodiments, the carbon (C) concentration ranges from low to high, where the carbon (C) concentration is lowest at the interface with the silicon channel layer 222 and highest at the interface with the second doped silicon layer 226b. In one or more embodiments, the carbon (C) concentration ranges from high to low, where the carbon (C) concentration is highest at the interface with the silicon channel layer 222 and lowest at the interface with the second doped silicon layer 226b. In one or more embodiments, the concentration of carbon (C) in the second interfacial layer 224b is in a range of from 0 atomic % to 2.5 atomic %, or in a range of from greater than 0 atomic % to 1 atomic %, or in a range of from greater than 0 atomic % to 0.9 atomic %, or in a range of from greater than 0 atomic % to 0.8 atomic %, or in a range of from greater than 0 atomic % to 0.7 atomic %, or in a range of from greater than 0 atomic % to 0.6 atomic %. In one or more embodiments, the concentration of dopant in the second interfacial layer 224b is greater than 0 atomic %, 0.01 atomic %, 0.02 atomic %, 0.03 atomic %, 0.04 atomic %, 0.05 atomic %, 0.06 atomic %, 0.07 atomic %, 0.08 atomic %, 0.09 atomic %, 0.1 atomic %, 0.15 atomic %, 0.2 atomic %, 0.25 atomic %, 0.3 atomic %, 0.35 atomic %, 0.4 atomic %, 0.45 atomic %, 0.5 atomic %, 0.55 atomic %, 0.6 atomic %, 0.65 atomic %, 0.7 atomic %, 0.75 atomic %, 0.8 atomic %, 0.85 atomic %, 0.9 atomic %, 0.95 atomic %, or 1.0 atomic %.

In one or more embodiments, the second interfacial layer 224b comprises a doped silicon germanium layer having a germanium concentration or germanium content in a range of from greater than 0 atomic % to 20 atomic % germanium, including in a range of from greater than 0 atomic % to 15 atomic % germanium, including in a range of from 5 atomic % to 15 atomic %, and including in a range of from 10 atomic % to 15 atomic %. In one or more embodiments, the second interfacial layer 224b comprises a doped silicon germanium layer having a germanium content of greater than 0 atomic %, including about 1 atomic %, about 2 atomic %, about 3 atomic %, about 4 atomic %, about 5 atomic %, about 6 atomic %, about 7 atomic %, about 8 atomic %, about 9 atomic %, about 10 atomic %, about 11 atomic %, about 12 atomic %, about 13 atomic %, about 14 atomic %, about 15 atomic %, about 16 atomic %, about 17 atomic %, about 18 atomic %, about 19 atomic %, or about 20 atomic %.

In one or more embodiments, the second interfacial layer 224b has any suitable thickness. In some embodiments, the second interfacial layer 224b has a thickness in a range of from greater than 0 nm to 10 nm, including in a range of from greater than 0 nm to 8 nm, including in a range of from greater than 0 nm to 5 nm, including in a range of from greater than 0 nm to 3 nm, including in a range of from 1 nm to 5 nm, or in a range of from 1 nm to 3 nm, or in a range of from 1 nm to 2.5 nm. In one or more embodiments, the second interfacial layer 224b has a thickness of about greater than 0 nm, about 0.5 nm, about 1 nm, about 1.5 nm, about 2 nm, about 2.5 nm, about 3 nm, about 3.5 nm, about 4 nm, about 4.5 nm, about 5 nm, about 5.5 nm, about 6 nm, about 6.5 nm, about 7 nm, about 7.5 nm, about 8 nm, about 8.5 nm, about 9 nm, about 9.5 nm, or about 10 nm.

The dopant in any of the interfacial layer 224, the second interfacial layer 224b, the first doped silicon layer 226, and the second doped silicon layer 226b can be any suitable dopant known to the skilled artisan. In some embodiments, the dopant comprises a Group III-V element. In some embodiments, the dopant comprises one or more of carbon (C), boron (B), nitrogen (N), phosphorus (P), or oxygen (O). In some embodiments, the dopant comprises one or more of carbon (C) or boron (B). In other embodiments, the dopant comprises carbon (C). In some embodiments, the dopant consists essentially of one or more of carbon or boron. In other embodiments, the dopant consists essentially of carbon (C). As used in this manner, the term “consists essentially of” means that the composition of the subject component is greater than or equal to 95%, 98%, 99% or 99.5% of the stated material. For example, a dopant consisting essentially of carbon and/or boron means that out of all dopant atoms, greater than or equal to 95% are carbon or boron. In some embodiments, the dopant comprises or consists essentially of carbon. In some embodiments, the dopant comprises or consists essentially of boron.

The various layers described can be formed by any suitable technique known to the skilled artisan. For example, one or more of the films can be formed by epitaxial growth, chemical vapor deposition, atomic layer deposition, physical vapor deposition, ion implantation, etc. In some embodiments, each of the silicon channel layer 222, interfacial layer 224, the second interfacial layer 224b, the first doped silicon layer 226, and the second doped silicon layer 226b are epitaxially grown. In some embodiments, each of the silicon channel layer 222, interfacial layer 224, the second interfacial layer 224b, the first doped silicon layer 226, and the second doped silicon layer 226b are independently grown at a temperature in the range of 500° C. to 800° C.

In one or more embodiments, the stress of the film stack 220 is modulated by the doped layers, which advantageously reduces bowing of the wafer upon which the film stack(s) 220 is deposited. In some embodiments, the overall bowing of the wafer is neutral after formation of 100 film stacks 220. In some embodiments, the overall bowing of the wafer is neutral after formation of 125, 150, 175, or 200 film stacks 220. As used in this manner, the term “neutral” means that there is less than or equal to 200 μm, 175 μm, 150 μm, 125 μm, 100 μm, 75 μm, 50 μm, 25 μm bow across the wafer surface; with the center of the wafer either bowing up or bowing down with respect to some or all of the edge regions. Some embodiments provide a method of doping epitaxial films in a controlled manner to result in reduced wafer bow of 30 μm or less for 1 μm tall stack making a 5 μm or greater DRAM stack height with neutral wafer bow.

In one or more embodiments, a method of making a 3D DRAM device is provided. In some embodiments, the method includes forming a plurality of film stacks 220, 220a, 220b on a substrate surface 212. Each of the film stacks 220, 220a, 220b may include a silicon channel layer 222. In one or more embodiments, a first interfacial layer 224 is formed on, or directly on, the silicon channel layer 222. In some embodiments, the first interfacial layer 224 comprises a doped silicon germanium layer having a dopant concentration of greater than 0 atomic % to 2.5 atomic % and having a germanium concentration in a range of from greater than 0 atomic % to 25 atomic %. In one or more embodiments, a first doped silicon layer 226 is formed on, or directly on, the first interfacial layer 224. In some embodiments, the first doped silicon layer 226 comprises a dopant having a dopant concentration in a range of from greater than 0 atomic % to 2.5 atomic %. In one or more embodiments, a sacrificial layer 228 is formed on, or directly on, the first doped silicon layer 226. In some embodiments, the sacrificial layer 228 comprises silicon germanium with a germanium concentration in a range of from greater than 10 atomic % to 25 atomic %. In one or more embodiments, the sacrificial layer 228 has a germanium concentration greater than the germanium concentration of the first interfacial layer 224. In one or more embodiments, a second doped silicon layer 226b is formed on, or directly on, the sacrificial layer 228. In some embodiments, the second doped silicon layer 226b comprises a dopant having a dopant concentration in a range of from greater than 0 atomic % to 2.5 atomic %. In one or more embodiments, a second interfacial layer 224b is formed on, or directly on, the second doped silicon layer 226b. In some embodiments, the second interfacial layer 224b comprises a doped silicon germanium layer having a dopant concentration of greater than 0 atomic % to 2.5 atomic % and having a germanium concentration in a range of from greater than 0 atomic % to 25 atomic %. In one or more embodiments, the second interfacial layer has a germanium concentration that is less than the germanium concentration of the sacrificial layer. In one or more embodiments, a memory hole opening 240 is formed through the plurality of film stacks 220, 220a, 220b to the substrate 210.

FIG. 2 illustrates a portion of the 3D DRAM device 100 of FIG. 1 at region II. In some embodiments of the method further comprise forming a memory hole opening 140 through all of the film stacks 120 to the substrate surface 112 (or a distance into the substrate 110) by lithography. The skilled artisan will understand how to form the memory hole opening 140 using lithography. As illustrated in FIG. 2B, in one or more embodiments, after formation of the memory hole opening 140, one or more of the sacrificial layer 128, the first doped silicon layer 124, the second doped silicon layer 126, the third doped silicon layer 126b, and the fourth doped silicon layer 124b may be completely or partially selectively etched from the film stacks 120 through the memory hole opening 140. FIG. 2B shows the sacrificial layer 128 removed leaving an opening 130. The skilled artisan will understand that the first doped silicon layer 124, for example, can be completely or partially removed through memory hole opening 140 while leaving the sacrificial layer 128. One skilled in the art recognizes that one or more of the sacrificial layer 128, the first doped silicon layer 124, the second doped silicon layer 126, the third doped silicon layer 126b, and the fourth doped silicon layer 124b may be completely or partially selectively etched depending upon the exact concentration of dopant and/or germanium, which determine the etch selectivity of each respective layer relative to the other layers in the film stack 120.

FIG. 4 illustrates a portion of the 3D DRAM device 200 of FIG. 2 at region III. In some embodiments of the method further comprise forming a memory hole opening 240 through all of the film stacks 220 to the substrate surface 212 (or a distance into the substrate 210) by lithography. The skilled artisan will understand how to form the memory hole channel 240 using lithography. As illustrated in FIG. 4B, in one or more embodiments, after formation of the memory hole opening 240, one or more of the sacrificial layer 228, the interfacial layer 224, the second interfacial layer 224b, the first doped silicon layer 226, and the second doped silicon layer 226b may be completely or partially selectively etched from the film stacks 220 through the memory hole opening 240. FIG. 4B shows the sacrificial layer 228 partially removed leaving a recess opening 230. The skilled artisan will understand that the first doped silicon layer 226, for example, can be completely or partially removed through memory hole opening 240 while leaving the sacrificial layer 228 and other layers. One skilled in the art recognizes that one or more of the sacrificial layer 228, the interfacial layer 224, the second interfacial layer 224b, the first doped silicon layer 226, and the second doped silicon layer 226b may be completely or partially selectively etched depending upon the exact concentration of dopant and/or germanium, which determine the etch selectivity of each respective layer relative to the other layers in the film stack 220.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of making a 3D DRAM device, the method comprising:
forming a plurality of film stacks on a substrate surface, each of the film stacks comprising:
a silicon channel layer,
a first doped silicon layer on the silicon channel layer, the first doped silicon layer comprising a first dopant having a first dopant concentration,
a second doped silicon layer on the first doped silicon layer, the second doped silicon layer comprising a second dopant having a second dopant concentration, the second dopant concentration greater than the first dopant concentration,
a sacrificial layer on the second doped silicon layer, the sacrificial layer comprising silicon germanium;
a third doped silicon layer on the sacrificial layer, the third doped silicon layer comprising a third dopant having a third dopant concentration, and
a fourth doped silicon layer on the third doped silicon layer, the fourth doped silicon layer comprising a fourth dopant having a fourth dopant concentration, the third dopant concentration greater than the fourth dopant concentration.

2. The method of claim 1, further comprising forming a memory hole opening through the plurality of film stacks to the substrate.

3. The method of claim 1, wherein the first dopant concentration, the second dopant concentration, the third dopant concentration, and the fourth dopant concentration are independently in a range of from greater than 0 atomic % to 2.5 atomic %.

4. The method of claim 1, wherein the silicon germanium has a germanium concentration in a range of from greater than 0 atomic % to 25 atomic %, and wherein the silicon germanium is doped with a dopant having a dopant concentration in a range of from greater than 0 atomic % to 2.5 atomic %.

5. The method of claim 1, wherein the silicon channel layer has a thickness in a range of from greater than 0 nm to 50 nm, and wherein each of the first doped silicon layer, the second doped silicon layer, the third doped silicon layer, the fourth doped silicon layer, and the sacrificial layer independently have a thickness in a range of from greater than 0 nm to 25 nm.

6. The method of claim 1, wherein the first dopant, the second dopant, the third dopant, and the fourth dopant independently comprise a Group III-V element.

7. The method of claim 6, wherein the first dopant, the second dopant, the third dopant, and the fourth dopant independently comprise one or more of carbon or boron.

8. The method of claim 1, wherein each of the silicon channel layer, the first doped silicon layer, the second doped silicon layer, the third doped silicon layer, the fourth doped silicon layer, and the sacrificial layer are epitaxially grown.

9. The method of claim 1, wherein each of the silicon channel layer, the first doped silicon layer, the second doped silicon layer, the third doped silicon layer, the fourth doped silicon layer, and the sacrificial layer are independently grown at temperatures in the range of 500° C. to 800° C.

10. The method of claim 1, wherein the substrate bows by an amount less than 200 μm when there are 100 film stacks.

11. A method of making a 3D DRAM device, the method comprising:
forming a plurality of film stacks on a substrate surface, each of the film stacks comprising:
a silicon channel layer,
a first interfacial layer on the silicon channel layer, the first interfacial layer comprising a doped silicon germanium layer having a first dopant with a first dopant concentration and having a germanium concentration %,
a first doped silicon layer on the first interfacial layer, the first doped silicon layer comprising a second dopant having a second dopant concentration,
a sacrificial layer on the first doped silicon layer, the sacrificial layer comprising silicon germanium with a germanium concentration, the germanium concentration of the sacrificial layer greater than the germanium concentration of the first interfacial layer,
a second doped silicon layer on the sacrificial layer, the second doped silicon layer comprising a third dopant having a third dopant concentration, and
a second interfacial layer on the second doped silicon layer, the second interfacial layer comprising a doped silicon germanium layer having a fourth dopant with a fourth dopant concentration and having a germanium concentration, the germanium concentration of the second interfacial layer less than the germanium concentration of the sacrificial layer.

12. The method of claim 11, further comprising forming a memory hole opening through the plurality of film stacks to the substrate.

13. The method of claim 11, wherein the first dopant concentration, the second dopant concentration, the third dopant concentration, and the fourth dopant concentration are independently in a range of from greater than 0 atomic % to 2.5 atomic %.

14. The method of claim 11, wherein the germanium concentration of the sacrificial layer, the germanium concentration of the first interfacial layer, and the germanium concentration of the second interfacial layer are independently in a range of from greater than 0 atomic % to 25 atomic %.

15. The method of claim 11, wherein the silicon channel layer has a thickness in a range of from greater than 0 nm to 50 nm, wherein the first doped silicon layer and the second doped silicon layer independently have a thickness in a range of from greater than 0 nm to 25 nm, and wherein the first interfacial layer and the second interfacial layer independently comprise an interfacial layer thickness in a range of from greater than 0 nm to 10 nm.

16. The method of claim 11, wherein the first dopant, the second dopant, the third dopant, and the fourth dopant independently comprise a Group III-V element.

17. The method of claim 16, wherein the first dopant, the second dopant, the third dopant, and the fourth dopant independently comprise one or more of carbon or boron.

18. The method of claim 11, wherein each of the silicon channel layer, the first doped silicon layer, the second doped silicon layer, the third doped silicon layer, the fourth doped silicon layer, and the sacrificial layer are epitaxially grown.

19. The method of claim 11, wherein each of the silicon channel layer, the first doped silicon layer, the second doped silicon layer, the third doped silicon layer, the fourth doped silicon layer, and the sacrificial layer are independently grown at temperatures in the range of 500° C. to 800° C.

20. The method of claim 11, wherein the substrate bows by an amount less than 200 μm when there are 100 film stacks.

21. A semiconductor superlattice structure comprising:
a plurality of film stacks on a semiconductor substrate, each of the plurality of film stacks comprising:
a silicon channel layer;
a first doped silicon layer on the silicon channel layer, the first doped silicon layer comprising a first dopant having a first dopant concentration;
a second doped silicon layer on the first doped silicon layer, the second doped silicon layer comprising a second dopant having a second dopant concentration, the second dopant concentration greater than the first dopant concentration;
a sacrificial layer on the second doped silicon layer, the sacrificial layer comprising silicon germanium;
a third doped silicon layer on the sacrificial layer, the third doped silicon layer comprising a third dopant having a third dopant concentration; and
a fourth doped silicon layer on the third doped silicon layer, the fourth doped silicon layer comprising a fourth dopant having a fourth dopant concentration, the third dopant concentration greater than the fourth dopant concentration.

22. The semiconductor superlattice structure of claim 21, further comprising a memory hole opening extending through the plurality of film stacks to the semiconductor substrate.

23. A semiconductor superlattice structure comprising:
a plurality of film stacks on a semiconductor substrate, each of the plurality of film stacks comprising
a silicon channel layer;
a first interfacial layer on the silicon channel layer, the first interfacial layer comprising a doped silicon germanium layer having a first dopant with a first dopant concentration and having a germanium concentration;
a first doped silicon layer on the first interfacial layer, the first doped silicon layer comprising a second dopant having a second dopant concentration;
a sacrificial layer on the first doped silicon layer, the sacrificial layer comprising silicon germanium with a germanium concentration, the germanium concentration of the sacrificial layer greater than the germanium concentration of the first interfacial layer;
a second doped silicon layer on the sacrificial layer, the second doped silicon layer comprising a third dopant having a third dopant concentration; and
a second interfacial layer on the second doped silicon layer, the second interfacial layer comprising a doped silicon germanium layer having a fourth dopant with a fourth dopant concentration and having a germanium concentration, the germanium concentration of the second interfacial layer less than the germanium concentration of the sacrificial layer.

24. The semiconductor superlattice structure of claim 23, further comprising a memory hole opening extending through the plurality of film stacks to the semiconductor substrate.

25. A non-transitory computer readable medium including instructions, that, when executed by a controller of a processing chamber, causes the processing chamber to perform the operations of the method of claim 1.

26. A non-transitory computer readable medium including instructions, that, when executed by a controller of a processing chamber, causes the processing chamber to perform the operations of the method of claim 11.
